(19) United States
(12) Patent Application Publication
(10) Pub. No.: US 2008/0116553 A1
(43) Pub. Date: May 22, 2008

(54) Wirebond Package Design for High Speed Data Rates

(75) Inventor: Frank Rossi, Burlington, VT (US)

Correspondence Address: DOWNS RACHLIN MARTIN PLLC, 199 MAIN ST, PO BO 190, BURLINGTON, VT, 05402-0190, US

(73) Assignee: INTERNATIONAL BUSINESS MACHINES CORPORATION, Armonk, NY (US)

(21) Appl. No.: 11/561,756

(22) Filed: Nov. 20, 2006

(51) Int. Cl. H01L 23/02

(52) U.S. Cl. 257/678

(57) ABSTRACT

A wirebond package design that reduces power supply noise and noise coupling using common mode shielding. The package design having lanes with wirebond connections. The wirebond connections have wirebond pads staggered along a longitudinal axis. The wirebond pads accommodate a plurality of shields that isolate differential pairs and adjacent lanes.

### FIELD OF THE INVENTION

The present invention generally relates to the field of semiconductor chip packages. In particular, the present invention is directed to a wirebond package design for high speed data rates.

### BACKGROUND

Designers of integrated circuits, such as, for example, ASIC devices, often encounter fundamental technical problems that require innovative design solutions. As supply voltages are decreasing, one such problem occurs due to excessive power supply noise. In general, power supply noise results from power supply inductance and instantaneous current draw which is not decreasing with the lower supply voltages. Designers, understanding that current draw is typically fixed, recognize that minimizing power supply inductance may be the only option to correct this problem. Unfortunately, this option often leads to unavoidable design trade-offs where designers must minimize the power supply noise at the expense of maintaining adequate data signal integrity.

### SUMMARY

In one embodiment, the present disclosure is directed to a semiconductor chip package connectable to an electrical ground and to a source of power that provides an electrical signal. The semiconductor chip package comprises a plurality of lanes that has a plurality of wirebond connections. The plurality of wirebond connections has at least one wirebond pad, at least one receiving differential pair, at least one transmission differential pair and a plurality of shields. The plurality of shields includes at least one first shield connected to at least one other of the plurality of shields for transmitting an electrical power signal, and at least one second shield connect to at least one other of the plurality of shields for transmitting an electrical ground signal. At least one electrical component is connected to the plurality of lanes.

In another embodiment, the present disclosure is directed to a lane used in a semiconductor chip wiring package and couplable to an electrical ground and to a power source for providing an electrical signal. The lane comprises at least one receiving differential pair and at least one transmission differential pair. The lane also includes a plurality of receiving shields couplable to the power source, at least two of the receiving shields are adjacent the receiving differential pair. The lane further includes a plurality of transmission shields couplable to the electrical ground, at least two of the transmission shields are adjacent the transmission differential pairs.

In a further embodiment, the present disclosure is directed to a method of reducing noise in a semiconductor chip package. The method comprises providing a semiconductor chip package with at least one lane having a plurality of wirebond connections, each of the plurality of wirebond connections has at least one wirebond pad, a first differential pair and a second differential pair. A first electrical signal is transmitted in the first differential pair. A second electrical signal is transmitted in the second differential pair. A third electrical signal is transmitted in at least two of the wirebond connections that are adjacent the first differential pair. A fourth electrical signal is transmitted in at least two of the wirebond connections that are adjacent the second differential pair.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a top plan view of a conventional semiconductor chip package;

FIG. 2 is a schematic view of a portion of a conventional semiconductor chip package;

FIG. 3 is a schematic view of one embodiment of a semiconductor chip package; and

FIG. 4 is a schematic view of another embodiment of a semiconductor chip package.

### DETAILED DESCRIPTION

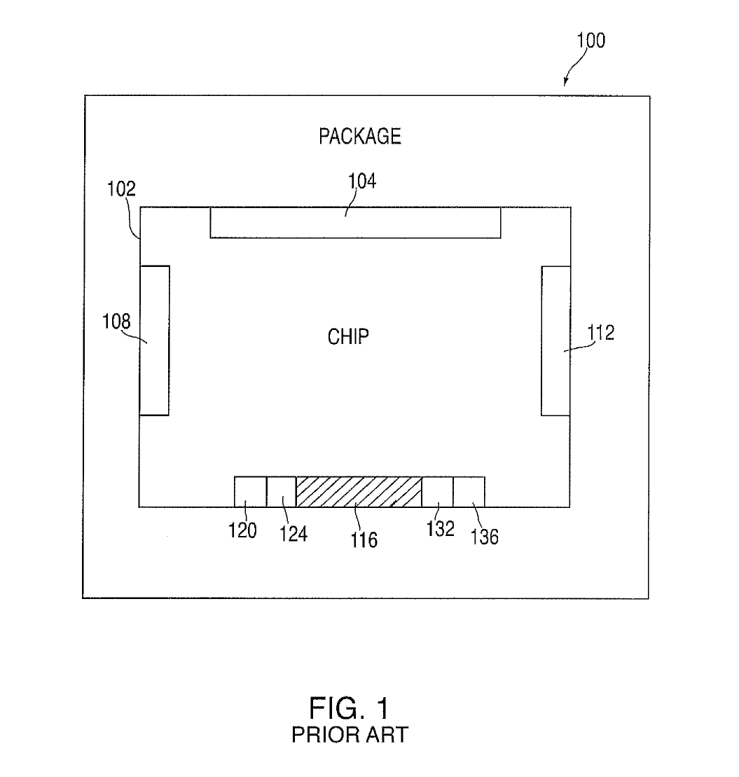

Referring now to the drawings, wherein like numerals indicate like elements, FIG. 1 illustrates a typical semiconductor chip package 100 that is known in the art. Package 100 may include a chip 102 having various electrical components and structures that are arranged in a manner to satisfy an overall design function. The details of these structures will not be discussed here, as they are generally understood by a person ordinarily skilled in the art, but are instead illustrated as input/outputs 104, 108 and 112, common block 116, and lanes 120, 124, 132 and 136.

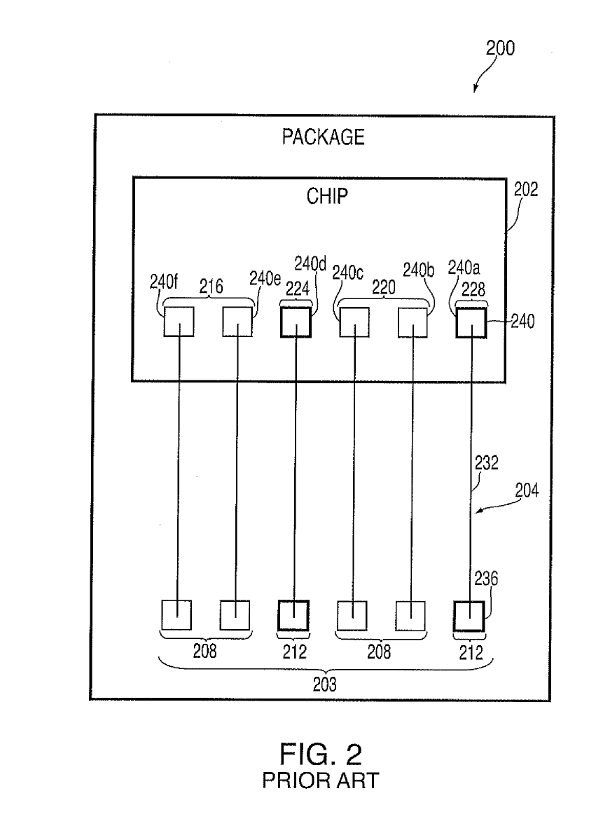

Referring now to FIG. 2, and also to FIG. 1, a semiconductor chip package 200 is illustrated. At a high level, package 200 may include a chip 202 having at least one lane 203. Those ordinarily skilled in the art will recognize that chip 202 may include several lanes 203. In one embodiment, lane 203 may include a plurality of wirebond connections 204 that perform designated electrical functions, as desired. The latter may be arranged in a variety of patterns, such as, for example, at least one differential pair 208. In operation, differential pair 208 transmits electrical data signals critical to the overall performance of semiconductor chip package 200. These transmissions often generate an electrical noise by-product that may affect the performance of one differential pair 208 located adjacent or otherwise proximate a second differential pair 208. This interference, more generally described as “cross-talk”, may necessitate that lane 203 include additional wirebond connections 204, or other discrete electrical components, that separate and isolate differential pairs 208. Accordingly, lane 203 may include at least one shield 212. The latter may be located between differential pairs 208, as shown in FIG. 2, or in other locations within lane 203, as desired. In general, shield 212 may carry a constant electrical signal, such as, for example, an analog voltage signal or analog ground signal. Alternatively, shield 212 may transmit other types of signals or be constructed in a manner such that the physical and material properties may exhibit suitable insulating properties and reduce “cross-talk” effects. Those ordinarily skilled in the art will recognize that this signal carried by shield 212 may originate from a constant source, such as the power supplied to semiconductor chip package 200, or may originate from another source consistent with the desired electrical design.

Referring again to FIGS. 1 and 2, those of ordinary skill in the art will recognize that differential pairs 208 may include, for example, at least one receiving differential pair 216 and at least one transmission differential pair 220. Pairs 216 and 220 may be arranged adjacent each other, as depicted in FIG. 2, or in some other orientation, as desired. In general, pair 216 and pair 220 transmit different electrical and data signals critical to the performance of semiconductor chip package 200. These signals may interfere with signals carried by differential pairs 208 positioned adjacent or proximate pairs 216 and 220, as described above. Thus, lane 203 may further include a receiving shield 224, in accordance with the present disclosure, that separates receiving differential pair 216 and transmission differential pair 220. Shield 224 may carry an analog voltage signal equivalent to the voltage supplied to lane 203. In addition, lane 203 may also include a transmission shield 228 that carries an analog ground signal or other similar signal, as desired. The latter, like shield 224, provides isolating characteristics that may be used to reduce interference effects, such as, for example, interference on adjacent lanes 203, e.g., lanes 120, 124, 132 and 136 (FIG. 1).

In general, receiving shield 224 and transmission shield 228 are wirebond connections similar to wirebond connection 204 discussed previously. Transmission shield 228 may include a bond wire 232, a packaging pad 236 and a wirebond pad 240. Those ordinarily skilled in the art will recognize the linear arrangement of wirebond pads 240 in differential pairs 208, receiving shield 224 and transmission shield 228, e.g., pads 240a, 240b, 240c, 240d, 240e and 240f, as a typical configuration for lane 203. This arrangement, although common in the art, limits the number and location of wirebond pads 240a-240f. This limitation prohibits the addition of certain other shielding mechanisms, such as, for example, other shields 212, within the confines of lane 203. Consequently, one skilled in the art will recognize that increasing the number of wirebond pads 240 will permit the addition of more shields 212, which will ultimately improve the overall performance of semiconductor chip package 200.

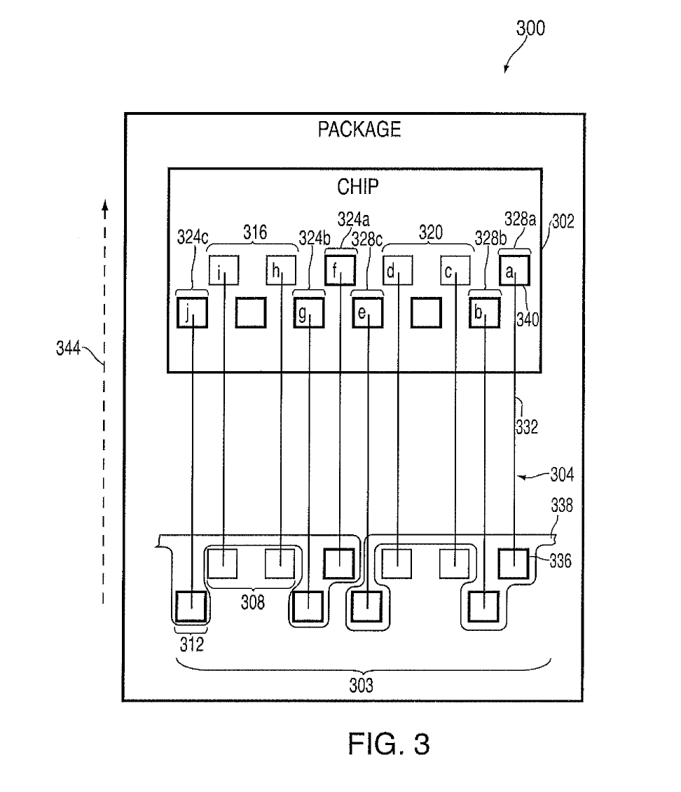

Accordingly, referring again to the drawings, FIG. 3 illustrates one embodiment of a semiconductor clip package 300. Identical numbering is used for like parts in package 200 and package 300, except that 300 series numbers are used in package 300. In general, package 300 may include a chip 302 having at least one lane 303. Although only one lane 303 is shown, those ordinarily skilled in the art will appreciate that chip 302 may include several of lane 303. Lane 303 may have a plurality of wirebond connections 304, as discussed above. Wirebond connections 304 may include one or more differential pairs 308 and a plurality of shields 312. The former often include a receiving differential pair 316 and a transmission differential pair 320, while the latter typically includes a receiving shield 324 and a transmission shield 328. Those ordinarily skilled in the art will recognize that lane 303, in accordance with the present disclosure, may include any number of shields 324, e.g., 324a, 324b and 324c, and shields 328, e.g., 328a, 328b and 328c. In one embodiment, at least two receiving shields 324, e.g., 324b and 324c, will be adjacent receiving differential pair 316 and at least two transmission shields 328, e.g., 328b and 328c, will be adjacent transmission differential pair 320.

In general, the number of shields 312 corresponds essentially to the arrangement of wirebond connection 304. In general, wirebond connection 304 may have a bond wire 332, a packaging pad 336 and a wirebond pad 340. Those ordinarily skilled in the art will recognize that several of packaging pad 336 may be connected using metallurgy 338. A linear arrangement of wirebond pads, discussed previously and known in the art, see, e.g., FIG. 2, provides a limited number of wirebond pads 340. In the present embodiment however, wirebond pads 340, e.g., 340a-340j, are staggered or longitudinally offset with respect to a longitudinal axis 344. This staggering increases the number of wirebond connections 304 in a given lane 303. In some applications, wirebond pads 340 will be staggered in a manner that creates two horizontal rows. Those ordinarily skilled in the art, however, will recognize that the number of offset locations available for wirebond pads 340 may vary depending on the design and manufacture of semiconductor chip package 300. The increased number of wirebond pads 340 accommodate additional receiving shields 324, e.g. 324b and 324c, and transmission shields 328, e.g., 328b and 328c. The former, discussed previously, effectively reduces “cross-talk” between differential pairs 316 and 320 and also maintains the length and loop height of bond wire 332, two dimensions critically considered in the design and manufacture of semiconductor chip package 300.

Further, with continued reference to FIG. 3, if desired, noise may be reduced by increasing the isolating characteristics of receiving shields 324, e.g., 324a, 324b and 324c and transmission shields 328, e.g., 328a, 328b and 328c. For example, a constant analog voltage signal may be applied to receiving shields 324 by coupling wirebond pads 340f, 340g and 340j. This coupling may be done through back-end metallurgy methods, known in the art, or by other means common to the manufacture processes associated with semiconductor chip package 300. In general, this coupling surrounds receiving differential pair 316 with a uniform analog voltage potential, creating a “common mode” potential with enhanced isolating and noise reduction properties. A similar configuration that couples wirebond pads 340a, 340b and 340c may also be used to surround transmission differential pair 320 with a uniform analog ground potential. Consequently, the use of the “common mode” potentials improves the performance of lane 303 by significantly reducing analog power inductance and analog voltage IR drop. These improvements provide wider operation ranges for semiconductor chip package 300 due, in part, to higher voltage levels from the reduced IR drop.

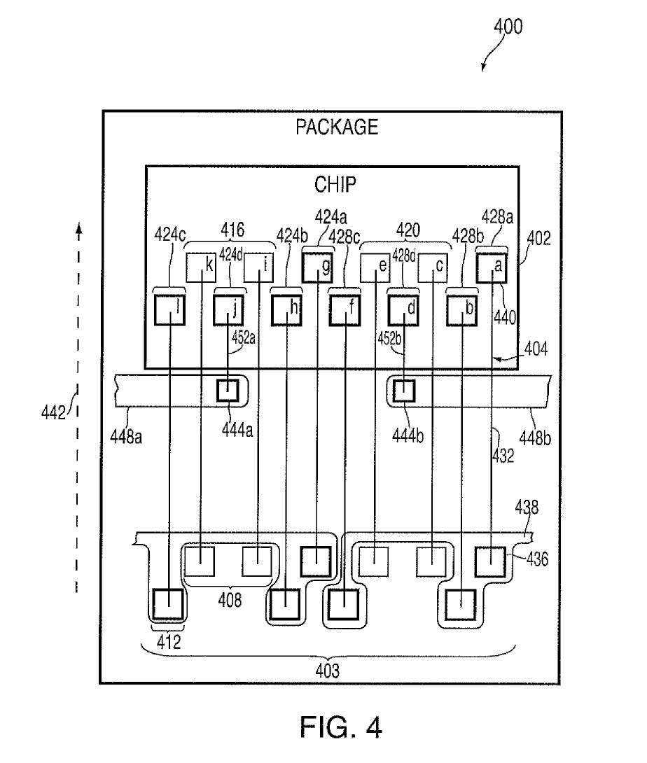

These improvements are also addressed by another embodiment detailed in FIG. 4. Referring to the drawings, FIG. 4 illustrates an embodiment of a semiconductor chip package 400. Identical numbering is used for like parts in package 300 and package 400, except that 400 series numbers are used in package 400. In general, package 400 may include a chip 402 having at least one lane 403. Although only one lane 403 is shown, those ordinarily skilled in the art will appreciate that chip 402 may include several of lane 403. Lane 403 may include a plurality of wirebond connections 404, as discussed above. Wirebond connections 404 may include differential pairs 408, e.g., receiving differential pair 416 and transmission differential pair 420, and a plurality of shields 412, e.g., receiving shields 424a-424d and transmission shields 428a-428d. Each wirebond connection 404 may have a bond wire 432, packaging pad 436, and wirebond pad 440 arranged in a staggered pattern with other wirebond pads with respect to a longitudinal axis 442, e.g., 440a-440l, and coupled to create the “common mode” potentials discussed above. Those ordinarily skilled in the art will recognize that several of packaging pad 436 may be connected using metallurgy 438. Lane 403 may also include receiving shield 424d and transmission shield 428d, located within receiving differential pair 408 and transmission differential pair 412, respectively. Generally, these additional shields 424d and 428d are connected, via terminating pads 444a and 444b, to downbonding pads 448a and 448b, respectively. Downbonding pads 448a and 448b will typically be recognized by those ordinarily skilled in the art as bus pads, such as, for example, a voltage bus or ground bus. These pads 448a and 448b may be located within lane 403 as desired, but preferably, the location of downbonding pads 448a and 448b creates a shortened bond wire 452a and 452b, respectively. Consequently, the shortened connections further improve the performance characteristics of lane 403 by providing an additional reduction in analog power inductance and analog voltage IR drop.

Several exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A semiconductor chip package connectable to a source of power that provides an electrical signal and to an electrical ground, the semiconductor chip package comprising:
a) a plurality of lanes, at least one of which has a plurality of wirebond connections, each of said plurality of wirebond connections having (i) at least one wirebond pad, (ii) at least one receiving differential pair, (iii) at least one transmission differential pair and (iv) a plurality of shields, wherein said plurality of shields includes at least one first shield connected to at least one other of said plurality of shields for transmitting an electrical power signal, and at least one second shield connected to at least one other of said plurality of shields for transmitting an electrical ground signal; and
b) at least one electrical component connected to said plurality of lanes.

2. The semiconductor chip package described in claim 1, wherein at least one of said plurality of shields is positioned adjacent at least one of said plurality of lanes.

3. The semiconductor chip package described in claim 1, wherein said wirebond pads are staggered.

4. The semiconductor chip package described in claim 1, wherein said receiving differential pair and at least one of said plurality of shields are of substantially equal lengths.

5. The semiconductor chip package described in claim 1, wherein said transmission differential pair and at least one of said plurality of shields are of substantially equal lengths.

6. The semiconductor chip package described in claim 1, wherein said receiving differential pair, said transmission differential pair, and said plurality of shields are of substantially equal lengths.

7. The semiconductor chip package described in claim 1, wherein at least one of said plurality of shields is connected to the electrical ground.

8. The semiconductor chip package described in claim 1, wherein at least one of said plurality of shields is connected to the source of power.

9. The semiconductor chip package described in claim 1, wherein said plurality of wirebond connections further includes terminating pads.

10. The semiconductor chip package described in claim 1, wherein said plurality of lanes further includes a voltage bus and a ground bus, wherein said voltage bus is operatively connected to at least one of said plurality of shields, and said ground bus is operatively connected to at least one of said plurality of shields.

11. A lane for use in a semiconductor chip wiring package and couplable to a power source for providing an electrical signal and to an electrical ground, said lane comprising:
a) at least one receiving differential pair;
b) at least one transmission differential pair;
c) a plurality of receiving shields couplable to the power source, wherein at least two of said plurality of receiving shields are adjacent said receiving differential pair; and
d) a plurality of transmission shields couplable to the electrical ground, wherein at least two of said plurality of transmission shields are adjacent said transmission differential pair.

12. The lane described in claim 11, wherein said plurality of receiving shields includes at least one first shield for transmitting an electrical power signal that is substantially equal to at least one other of said plurality of receiving shields.

13. The lane described in claim 11, wherein said plurality of transmission shields includes at least one second shield for transmitting an electrical ground signal that is substantially equal to at least one other of said plurality of transmission shields.

14. The lane described in claim 11, wherein said at least one receiving differential pair, said at least one transmission differential pair, said plurality of receiving shields and said plurality of transmission shields are of substantially equal lengths.

15. The lane described in claim 11, further comprising a voltage bus and a ground bus, wherein said voltage bus is connected to the power source and said plurality of receiving shields, and said ground bus is connected to said electrical ground and said plurality of transmission shields.

16. A method of reducing noise in a semiconductor chip package, the method comprising:
a) providing a semiconductor chip package with at least one lane having a plurality of wirebond connections, each of said plurality of wirebond connections has at least one wirebond pad, a first differential pair and a second differential pair;
b) transmitting a first electrical signal in the first differential pair;
c) transmitting a second electrical signal in the second differential pair;
d) transmitting a third electrical signal in at least two of said wirebond connections that are adjacent the first differential pair; and
e) transmitting a fourth electrical signal in at least two of said wirebond connections that are adjacent the second differential pair.

17. The method as described in claim 16, further comprising staggering said wirebond pads along a longitudinal axis.

18. The method as described in claim 16, further comprising downbonding at least one of said wirebond connections.
